(19) United States
(12) Patent Application Publication
(10) Pub. No.: US 2026/0371495 A1
(43) Pub. Date: Nov. 19, 2026

(54) WIRE-EMBEDDED METAL-CLAD LAMINATE, CIRCUIT BOARD, LED LIGHT STRIP, AND FABRICATION METHOD THEREFOR

(71) Applicant: Dingfeng WANG, Shenzhen (CN)

(72) Inventors: Dingfeng WANG, Shenzhen (CN); Hongxin DAI, Tongling (CN); Lei XU, Tongling (CN); Shengqi WANG, Tongling (CN); Wenhong XU, Tongling (CN)

(21) Appl. No.: 19/480,354

(22) PCT Filed: Sep. 12, 2023
(86) PCT No.: PCT/CN2023/118252

§ 371 Date: Oct. 30, 2025

(30) Foreign Application Priority Data
Apr. 30, 2023 (CN) 202310520947.4
Apr. 30, 2023 (CN) 202321081863.7

(51) Int. Cl. H05K 3/02; H05K 1/181

(52) U.S. Cl. CPC H05K 3/02; H05K 1/181; H05K 2201/10106; H05K 2203/0548

(57) ABSTRACT

Provided are a wire-embedded metal-clad laminate, a circuit board, an LED (Light Emitting Diode) light strip, and a fabrication method therefor. The circuit board includes a back solder mask, an intermediate circuit layer, and a front circuit layer. The back solder mask, the intermediate circuit layer and the front circuit layer are successively and vertically stacked. The circuit board further includes an adhesive, and the adhesive is configured to bond the back solder mask, the intermediate circuit layer and the front circuit layer together, the front circuit layer and the intermediate circuit layer overlap at partial positions to form double-layer metal positions, the front circuit layer and the intermediate circuit layer do not overlap at partial positions to form single-layer metal positions, and a metal thickness of the double-layer metal position is greater than that of the single-layer metal position. At the double-layer metal position, the front circuit layer and the intermediate circuit layer are bonded and fixed by the adhesive, and the front circuit layer is in conduction with the intermediate circuit layer. The circuit board further includes a front solder mask, which is arranged on the front circuit layer and/or the intermediate circuit layer. An intermediate insulating film is omitted, so that fabrication costs of the circuit board and the LED light strip are reduced.

### TECHNICAL FIELD

The present disclosure relates to the field of LED (Light Emitting Diode) light strips, and in particular to a wire-embedded metal-clad laminate, a circuit board, an LED light strip, and a fabrication method therefor.

### BACKGROUND

LED light strip is fabricated by soldering an LED-containing element to a single-layer flexible circuit board or a double-layer flexible circuit board. When manufacturing the light strip using the double-layer circuit board, since there are upper and lower circuit layers, one layer is generally dedicated to arranging a main line connected to a power supply, on which a wider main line can be arranged, the wider main line has a large current-carrying capacity and is suitable for fabricating a longer light strip. When fabricating a light strip using the single-layer circuit board, since the main line and all other lines can only be arranged on one circuit layer, a space occupied by the main line is small, resulting in a narrow main line with low current-carrying capacity, which is not suitable for fabricating the longer light strip. The flexible circuit board is fabricated by forming a circuit on a flexible metal-clad laminate by removing unnecessary copper by etching or die-cutting. In the prior art, a double-layer flexible metal-clad laminate for a double-layer flexible circuit board is formed by bonding and insulating two layers of copper foils by an intermediate insulating layer. The first type is a flexible metal-clad laminate formed by bonding two copper foils by a polyimide film, which is called an adhesive-free flexible metal-clad laminate in the industry, and polyimide has good insulation and stability. The second type is a double-layer flexible metal-clad laminate formed by applying adhesives (the adhesive is generally an epoxy adhesive or acrylic adhesive) to both sides of the polyimide film and bonding the two copper foil layers together, which is called a double-layer metal-clad laminate with the adhesive. There are three insulating layers, with a polyimide film in the middle, which provides excellent insulation and stability. The third type is a double-layer flexible metal-clad laminate formed by applying adhesives to both sides of a PET (Polyethylene Terephthalate) or PEN (Polyethylene Naphthalate) film and then bonding two copper foil layers to both sides, respectively. The PET or PEN film in the middle also offers good insulation and stability.

The intermediate insulating film has two functions: (1) adhesion: the insulating film is configured to connect a front circuit layer and a back circuit layer into a whole; and (2) Insulation function: the front circuit layer from the back circuit layer are insulated and separated by the insulating film. This structure has the following defects: (1) Because the insulating film is required to arranged to isolate circuits on both sides, the insulating film occupies a high cost in LED strip circuit board, which makes it difficult to further reduce the production cost of the LED light strip; (2) because the front circuit layer and the back circuit layer need to be connected by arranging a conducting layer on a wall of a via hole and then plating copper; or the two layers of lines can be electrically connected by soldering in the holes, which increases the cost. In addition, cheaper aluminum cannot be used to replace copper in these two connection modes, this is because the process of electroplating copper on the aluminum surface is complicated, leading to higher cost of achieving conduction through copper plating; and aluminum has poor solderability and is also unsuitable for conducting the circuits on both sides via soldering. The cost of copper is much more expensive than that of aluminum, which also limits the further reduction of the fabrication cost of the LED light strip with double panels.

Therefore, it is necessary to improve and optimize the existing LED light strip.

### SUMMARY

The present disclosure is intended to at least solve one of the problems in the prior art. To this end, the present disclosure provides a wire-embedded metal-clad laminate, a circuit board, an LED light strip, and a fabrication method therefor. An intermediate insulating film is omitted, one circuit layer is allowed to be fabricated by using aluminum or other cheaper metal, thereby reducing the fabrication cost of the circuit board and the LED light strip.

The technical solution adopted by the present disclosure to solve the technical problem is as follows.

In a first aspect, an embodiment of the present disclosure provides a fabrication method for a wire-embedded metal-clad laminate, including:
preparing a conductor, a metal foil, and an adhesive, adhering and fixing the conductor to the metal foil by the adhesive, fabricating a back solder mask on the conductor, where an intermediate circuit layer is formed by the conductor; or preparing metal foils and an adhesive, and combining two layers of metal foils together by the adhesive, and carrying out die-cutting on one layer of metal foil by a die-cutting method to remove unnecessary metal and form an intermediate circuit layer, and fabricating a back solder mask on the intermediate circuit layer; or preparing a thin film, a metal foil and a conductor, applying an adhesive on the metal foil or on the metal foil and the thin film, vertically stacking the thin film, the conductor and the metal foil to integrate the thin film, the conductor and the metal foil, where the conductor is located between the thin film and the metal foil to form an intermediate circuit layer; or preparing a thin film with a metal layer and a metal foil, fabricating the metal layer on the thin film into an intermediate circuit layer by an etching or die-cutting method, applying an adhesive on the metal foil or the intermediate circuit layer, and vertically stacking the thin film with the intermediate circuit layer and the metal foil to integrate the thin film, the intermediate circuit layer and the metal foil, where the intermediate circuit layer is located between the thin film and the metal foil;
the metal foil overlaps with the intermediate circuit layer at partial positions to form double-layer metal positions, the metal foil forms a single-layer metal position at a position other than the intermediate circuit layer, and a metal thickness of the double-layer metal position is greater than that of the single-layer metal position; at the double-layer metal position, the metal foil and the intermediate circuit layer are bonded and fixed by the adhesive, and the metal foil is in conduction with the intermediate circuit layer.

Alternatively, the double-layer metal position is provided with piercing holes, which penetrate the adhesive, penetrate the adhesive and the metal foil, penetrate the adhesive, and the intermediate circuit layer, or penetrate the adhesive, the metal foil and the intermediate circuit layer, such that the metal foil and the intermediate circuit layer are in contact and conduction with each other at a part or all of the piercing holes.

Alternatively, the intermediate circuit layer is made of copper, aluminum, copper-clad aluminum, copper-aluminum composite, or copper-clad steel; and the metal foil on the intermediate circuit layer is made of copper, copper-aluminum composite, nickel-coated aluminum, or tin-coated aluminum.

Alternatively, the adhesive is an acrylic adhesive, epoxy adhesive or polyurethane adhesive in a semi-cured state.

A first aspect embodiment of the present disclosure has at least one of the following beneficial effects: the intermediate circuit layer and the metal foil are directly bonded by means of the adhesive, the characteristics that the metal foil and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the metal foil is abandoned, and the fabrication cost of the wire-embedded metal-clad laminate is reduced. Because the adhesive is in an uncured state when the intermediate circuit layer and the metal foil are bonded and fixed by the adhesive, the adhesive between the intermediate circuit layer and the metal foil is partially squeezed away in the pressing process to promote the contact and conduction between the intermediate circuit layer and the metal foil, making it unnecessary to form via holes on the metal foil, and allowing one of the circuit layers to be made of aluminum. This avoids the problems in the prior art that electroplated copper and solder either fail to combine with aluminum or involving complex processes, so that the fabrication cost of the wire-embedded metal-clad laminate is further reduced, and the structure of the wire-embedded metal-clad laminate is simplified. Canceling the use of the insulating film also can reduce the weight of the wire-embedded metal-clad laminate. Therefore, the fabricated circuit board and LED light strip have lighter weight, which is beneficial to the hanging use of the long LED light strip and can prevent the long LED light strip from loosening or breaking due to its own weight.

In a second aspect, an embodiment of the present disclosure provides a fabrication method for a circuit board, including the fabrication method for a wire-embedded metal-clad laminate according to any embodiment in the first aspect, and further including fabricating a metal foil on an intermediate circuit layer into a circuit to form a front circuit layer, and fabricating a front solder mask on the front circuit layer.

Alternatively, the fabrication method for a circuit board further includes carrying out die-cutting on the metal foil by a die-cutting method before an adhesive between the metal foil and the intermediate circuit layer is cured, and tearing away unnecessary metal to form the front circuit layer by the metal foil; or after the adhesive between the metal foil and the intermediate circuit layer is cured, etching the metal foil by an etching method to form the front circuit layer.

Alternatively, the front circuit layer is fabricated by the die-cutting method, the front solder mask is a cover film with an adhesive, the cover film is bonded to the front circuit layer, and then pressing and heating are carried out to cure the adhesive and the adhesive on the cover film; or the front circuit layer is fabricated by the die-cutting method, the front solder mask is solder mask ink, the wire-embedded metal-clad laminate is die-cut to fabricate a circuit, and then pressed; then the solder mask ink is printed on the front circuit layer and heated, with the adhesive and the solder mask ink cured while heating.

Alternatively, the front circuit layer is fabricated by the etching method, the metal-clad laminate is pressed and heated for curing, and then the metal foil is etched to form the front circuit layer, the front solder mask is a cover film with an adhesive, the cover film is bonded to the front circuit layer, and pressing and heating are carried out to cure the adhesive on the cover film; or the front circuit layer is fabricated by the etching method, the metal-clad laminate is cured by pressing and heating, and the metal foil is etched to form the front circuit layer; the front solder mask is solder mask ink, the solder mask ink is printed on the front circuit layer, and the solder mask ink is cured by heating.

In a second aspect, an embodiment of the present disclosure further provides another fabrication method for a circuit board, including the following steps: preparing a single-sided metal-clad laminate and a conductor, fabricating a metal layer on the single-sided metal-clad laminate into an intermediate circuit layer by a die-cutting method or etching method, bonding the conductor to the front of the intermediate circuit layer by an adhesive, where the front circuit layer is formed by the conductor, so that the front circuit layer and the intermediate circuit layer overlap at partial positions to form double-layer metal positions, and the front circuit layer and the intermediate circuit layer do not overlap at partial positions to form single-layer metal positions, and a metal thickness of the double-layer metal position is greater than that of the single-layer metal position; at the double-layer metal position, bonding and fixing the front circuit layer and the intermediate circuit layer by the adhesive, and enabling the front circuit layer to be in conduction with the intermediate circuit layer; and disposing a front solder mask on the front circuit layer and/or the intermediate circuit layer.

Alternatively, the double-layer metal position is provided with piercing holes, which penetrate the adhesive, penetrate the adhesive and the front circuit layer, penetrate the adhesive and the intermediate circuit layer, or penetrate the adhesive, the front circuit layer and the intermediate circuit layer, such that the front circuit layer and the intermediate circuit layer are in electric contact with each other at a part or all of the piercing holes.

A second aspect embodiment of the present disclosure has at least one of the following beneficial effects: the intermediate circuit layer and the front circuit layer are directly bonded by means of the adhesive, the characteristics that the front circuit layer and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the front circuit layer is abandoned, and the fabrication cost of the circuit board is reduced. Because the adhesive is in an uncured state when the intermediate circuit layer and the front circuit layer are bonded and fixed by the adhesive, the adhesive between the intermediate circuit layer and the front circuit layer is partially squeezed away in the pressing process to promote the contact and conduction between the intermediate circuit layer and the front circuit layer, making it unnecessary to form via holes in the front circuit layer, and allowing one of the circuit layers to be made of aluminum. This avoids the problems in the prior art that electroplated copper and solder either fail to combine with aluminum or involving complex processes, so that the fabrication cost of the circuit board is further reduced, and the structure of the circuit board is simplified. Canceling the use of the insulating film also can reduce the weight of the circuit board. Therefore, the fabricated circuit board and LED light strip have lighter weight, which is beneficial to the hanging use of the long LED light strip and can prevent the long LED light strip from loosening or breaking due to its own weight.

In a third aspect, an embodiment of the present disclosure provided a wire-embedded metal-clad laminate, including a back solder mask, an intermediate circuit layer, and a metal foil, where the back solder mask, the intermediate circuit layer and the metal foil are vertically stacked in turn, an adhesive is formed between the back solder mask and the metal foil, and the back solder mask, the intermediate circuit layer and the metal foil are bonded together by the adhesive, the metal foil overlaps with the intermediate circuit layer at partial positions to form double-layer metal positions, the metal foil forms a single-layer metal position at a position other than the intermediate circuit layer, and a metal thickness of the double-layer metal position is greater than that of the single-layer metal position; and at the double-layer metal position, the metal foil and the intermediate circuit layer are bonded and fixed by the adhesive, and the metal foil is in conduction with the intermediate circuit layer.

Alternatively, the double-layer metal position is provided with piercing holes, which penetrate the adhesive, penetrate the adhesive and the metal foil, penetrate the adhesive and the intermediate circuit layer, or penetrate the adhesive, the metal foil and the intermediate circuit layer, such that the metal foil and the intermediate circuit layer are in electric contact with each other at a part or all of the piercing holes.

Alternatively, the intermediate circuit layer is made of copper, aluminum, copper-clad aluminum, copper-aluminum composite, or copper-clad steel; and the metal foil on the intermediate circuit layer is made of copper, copper-aluminum composite, nickel-coated aluminum, or tin-coated aluminum.

A third aspect embodiment of the present disclosure has at least one of the following beneficial effects: the intermediate circuit layer and the metal foil are directly bonded by means of the adhesive, the characteristics that the metal foil and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the metal foil is abandoned, and the fabrication cost of the wire-embedded metal-clad laminate is reduced. Because the adhesive is in an uncured state when the intermediate circuit layer and the metal foil are bonded and fixed by the adhesive, the adhesive between the intermediate circuit layer and the metal foil is partially squeezed away in the pressing process to promote the contact and conduction between the intermediate circuit layer and the metal foil, making it unnecessary to form via holes on the metal foil, and allowing one of the circuit layers to be made of aluminum. This avoids the problems in the prior art that electroplated copper and solder either fail to combine with aluminum or involving complex processes, so that the fabrication cost of the wire-embedded metal-clad laminate is further reduced, and the structure of the wire-embedded metal-clad laminate is simplified. Canceling the use of the insulating film also can reduce the weight of the wire-embedded metal-clad laminate. Therefore, the fabricated circuit board and LED light strip have lighter weight, which is beneficial to the hanging use of the long LED light strip and can prevent the long LED light strip from loosening or breaking due to its own weight.

In a fourth aspect, an embodiment of the present disclosure provides a circuit board, including a back solder mask, an intermediate circuit layer, and a front circuit layer, where the back solder mask, the intermediate circuit layer and the front circuit layer are vertically stacked in turn; the circuit board further includes an adhesive, the adhesive is configured to bond the back solder mask, the intermediate circuit layer and the front circuit layer together, the front circuit layer and the intermediate circuit layer overlap at partial positions to form double-layer metal positions, the front circuit layer and the intermediate circuit layer do not overlap at partial positions to form single-layer metal positions, and a metal thickness of the double-layer metal position is greater than that of the single-layer metal position; at the double-layer metal position, the front circuit layer and the intermediate circuit layer are bonded and fixed by the adhesive, and the front circuit layer is in conduction with the intermediate circuit layer; and the circuit board further includes a front solder mask, which is arranged on the front circuit layer and/or the intermediate circuit layer.

Alternatively, the double-layer metal position is provided with piercing holes, which penetrate the adhesive, penetrate the adhesive and the front circuit layer, penetrate the adhesive and the intermediate circuit layer, or penetrate the adhesive, the front circuit layer and the intermediate circuit layer, such that the front circuit layer and the intermediate circuit layer are in electric contact with each other at a part or all of the piercing holes.

Alternatively, the adhesive between the front circuit layer and the intermediate circuit layer has a thickness of 3 μm to 100 μm.

Alternatively, the front solder mask is a cover film, or solder mask ink.

Alternatively, each of the front circuit layer and the intermediate circuit layer is made of one or two of copper, aluminum, or a combination of copper-aluminum, copper-steel, aluminum-nickel, or aluminum-tin, and the front circuit layer and the intermediate circuit layer are made of a same metal or different metals.

Alternatively, when either of the front circuit layer or the intermediate circuit layer is made of aluminum, the other is a metal other than aluminum.

Alternatively, the adhesive is an acrylic adhesive, epoxy adhesive, or polyurethane adhesive.

A fourth aspect embodiment of the present disclosure has at least one of the following beneficial effects: the intermediate circuit layer and the front circuit layer are directly bonded by means of the adhesive, the characteristics that the front circuit layer and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the front circuit layer is abandoned, and the fabrication cost of the circuit board is reduced. Because the adhesive is in an uncured state when the intermediate circuit layer and the front circuit layer are bonded and fixed by the adhesive, the adhesive between the intermediate circuit layer and the front circuit layer is partially squeezed away in the pressing process to promote the contact and conduction between the intermediate circuit layer and the front circuit layer, making it unnecessary to form via holes in the front circuit layer, and allowing one of the circuit layers to be made of aluminum. This avoids the problems in the prior art that electroplated copper and solder either fail to combine with aluminum or involving complex processes, so that the fabrication cost of the circuit board is further reduced, and the structure of the circuit board is simplified. Canceling the use of the insulating film also can reduce the weight of the circuit board. Therefore, the fabricated circuit board and LED light strip have lighter weight, which is beneficial to the hanging use of the long LED light strip and can prevent the long LED light strip from loosening or breaking due to its own weight.

In a fifth aspect, an embodiment of the present disclosure provides an LED light strip, including the circuit board according to any one embodiment in the fourth aspect, and further including an electronic component soldered to a front circuit layer or an intermediate circuit layer.

Alternatively, a double-layer metal position is provided with a plurality of piercing holes, conductive substances are arranged in part or all of the piercing holes, and the front circuit layer and the intermediate circuit layer are electrically connected by the conductive substance.

Alternatively, the conductive substance is tin or copper.

A fifth aspect embodiment of the present disclosure has at least one of the following beneficial effects: the intermediate circuit layer and the front circuit layer are directly bonded by means of the adhesive, the characteristics that the front circuit layer and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the front circuit layer is abandoned, and the fabrication cost of the circuit board is reduced. Because the adhesive is in an uncured state when the intermediate circuit layer and the front circuit layer are bonded and fixed by the adhesive, the adhesive between the intermediate circuit layer and the front circuit layer is partially squeezed away in the pressing process to promote the contact and conduction between the intermediate circuit layer and the front circuit layer, making it unnecessary to form via holes in the front circuit layer, and allowing one of the circuit layers to be made of aluminum. This avoids the problems in the prior art that electroplated copper and solder either fail to combine with aluminum or involving complex processes, so that the fabrication cost of the circuit board is further reduced, and the structure of the circuit board is simplified. Canceling the use of the insulating film also can reduce the weight of the circuit board. Therefore, the fabricated circuit board and LED light strip have lighter weight, which is beneficial to the hanging use of the long LED light strip and can prevent the long LED light strip from loosening or breaking due to its own weight.

### BRIEF DESCRIPTION OF THE DRAWINGS

FIG. 1 is a diagram of a front structure of a thin film according to an embodiment of the present disclosure;

FIG. 2 is a sectional diagram of a thin film in FIG. 1 after being coated with an adhesive;

FIG. 3 is a diagram of a planar structure after a conductor is bonded to an adhesive-coated film shown in FIG. 2;

FIG. 4 is a diagram of a sectional structure of FIG. 3;

FIG. 5 is a diagram of a planar structure of a hole-free metal foil;

FIG. 6 is a diagram of a planar structure after a metal foil shown in FIG. 5 is bonded to a structure shown in FIG. 3;

FIG. 7 is a diagram of a planar structure of a structure shown in FIG. 6 after a metal foil is etched into a front circuit layer;

FIG. 8 is a diagram of a planar structure of a structure shown in FIG. 7 when a front solder mask layer is fabricated;

FIG. 9 is a diagram of a planar structure of an adhesive-backed metal foil with a piercing hole;

FIG. 10 is a diagram of a planar structure after an adhesive-backed metal foil shown in FIG. 9 is bonded to a structure shown in FIG. 3;

FIG. 11 is a diagram of a planar structure of a structure shown in FIG. 10 after a metal foil is etched into a front circuit layer;

FIG. 12 is a diagram of a planar structure of a structure shown in FIG. 11 when a front solder mask is fabricated;

FIG. 13 is an exploded view of a thin film and a metal foil with adhesive applied thereto;

FIG. 14 is a sectional diagram of a wire-embedded metal-clad laminate when structures shown in FIG. 13 are integrated;

FIG. 15 is an exploded view of a metal foil with an adhesive coated thereto;

FIG. 16 is a sectional diagram of a wire-embedded metal-clad laminate when structures shown in FIG. 15 are integrated;

FIG. 17 is a diagram of a planar structure when a conductor is bonded to an intermediate circuit layer (a front circuit layer is formed by the conductor);

FIG. 18 is a diagram of a planar structure when a front solder mask is fabricated based on FIG. 17;

FIG. 19 is a diagram of a sectional structure of A-A in FIG. 17 (for the convenience of placing drawings, the cross section is rotated 90° counterclockwise);

FIG. 20 is a diagram of a sectional structure of FIG. 19 after a front solder mask fabricated;

FIG. 21 is a cross-sectional diagram of a single circuit board in a transverse direction (a cross-section along a length direction, since the cross-section does not pass through a front circuit layer, the front circuit layer is not shown);

FIG. 22 is a cross-sectional diagram of FIG. 21 when a front solder mask is fabricated;

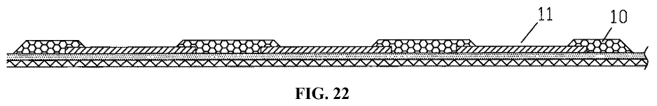

FIG. 23 is a cross-sectional diagram of a single circuit board in a longitudinal direction (a cross section in a width direction);

FIG. 24 is a cross-sectional diagram of FIG. 23 when a front solder mask is fabricated.

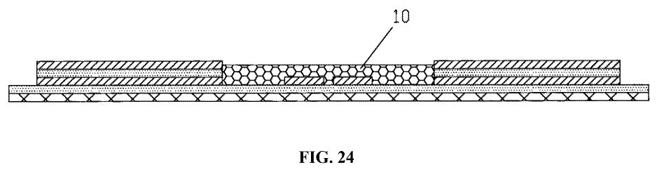

Reference numerals are as follows: 1—thin film; 2—conductor; 3—metal foil; 4—back solder mask; 5—intermediate circuit layer; 6—front circuit layer; 7—adhesive; 8—double—layer metal position; 9—single-layer metal position; 10—front solder mask; 11—bonding pad; 12—piercing hole.

### DETAILED DESCRIPTION OF THE EMBODIMENTS

To make the objectives, technical solutions and advantages of the present disclosure more clearly, the embodiments of the present disclosure are described in detail below with reference to accompanying drawings. It should be noted that the embodiments below and features in the embodiments can be mutually combined in the case of no conflict.

Numerous different implementations or examples are provided below to implement methods and structures in the present disclosure.

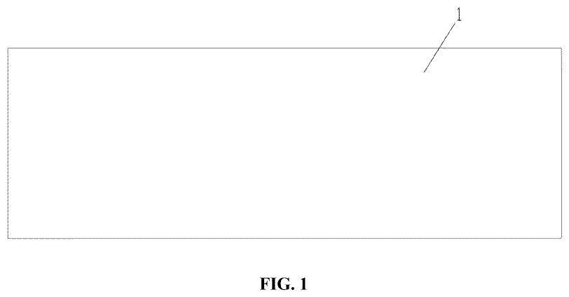

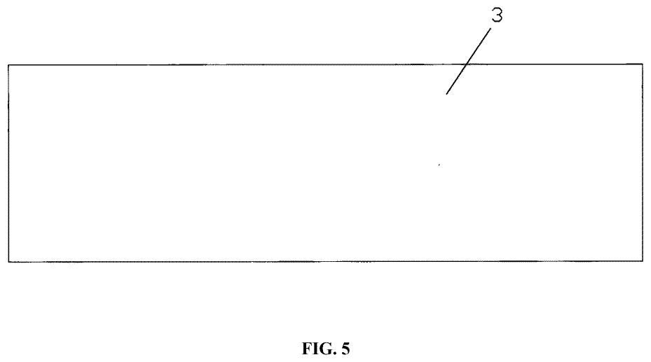

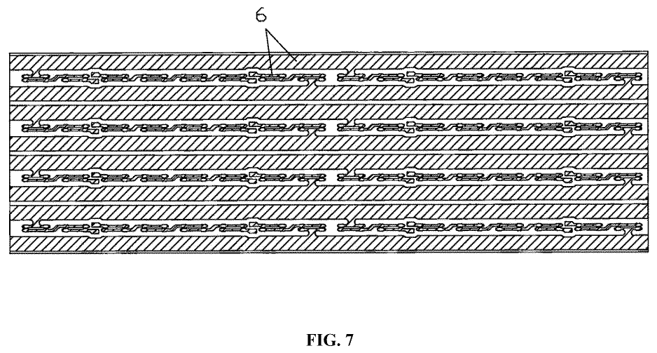

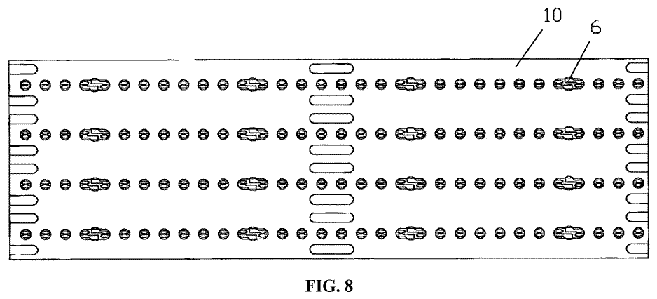

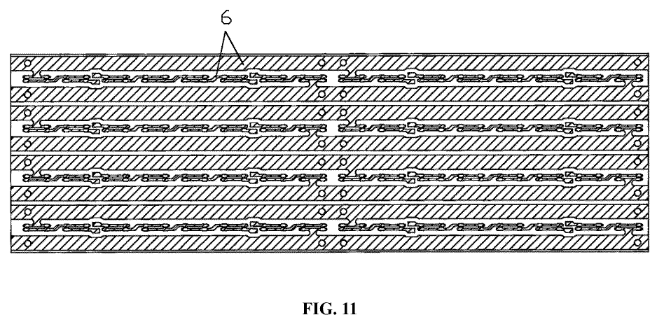

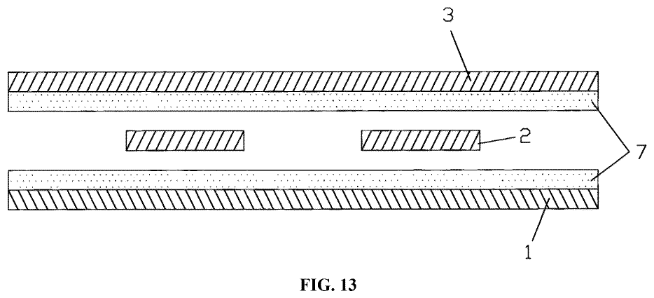

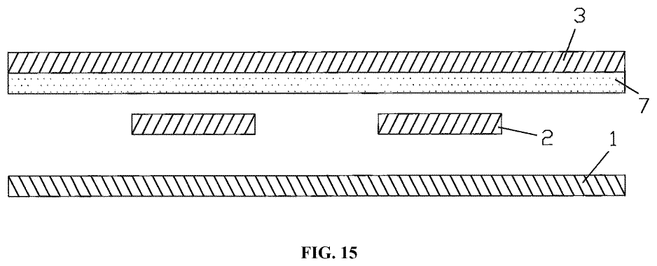

With reference to FIG. 1 to FIG. 20, an embodiment of a first aspect of the present disclosure provides a fabrication method for a wire-embedded metal-clad laminate.

### Embodiment 1

An aluminum conductor, a copper metal foil and an adhesive are prepared, the adhesive is a commercially available acrylic adhesive, and the aluminum conductor is bonded and fixed to the copper metal foil by the adhesive. Specifically, the adhesive can be coated on the aluminum conductor or the copper metal foil, and then the aluminum conductor and the copper foil are directly bonded. After the bonding is completed, a PET film is used as a back solder mask, the adhesive is coated on the back solder mask, and then the back solder mask is bonded to the aluminum conductor. The adhesive on the back solder mask is also bonded to the copper metal foil at the same time, so that the aluminum conductor, the copper metal foil and the back solder mask are firmly bonded into a whole to form a wire-embedded metal-clad laminate, where the conductor is sandwiched between the back solder mask and the copper metal foil to form an intermediate circuit layer, so that the aluminum conductor, the copper metal foil and the back solder mask are firmly bonded into a whole. After bonding, the wire-embedded metal-clad laminate can be pressed by a pressing machine, where the strength and conditions of pressing are well-known techniques in this field, and thus will not be repeated here.

### Embodiment 2

A copper metal foil and an adhesive are prepared, the adhesive is a commercially available epoxy adhesive, a part of the copper metal foil is coated with the adhesive on one side, and the copper metal foil coated with the adhesive and the copper metal foil not coated with the adhesive are bonded face to face, so that the two layers of metal foil are combined together through the adhesive. Alternatively, the adhesive can be coated on all copper metal foils, and the copper metal foils with the adhesive are attached face to face, so that the two layers of copper metal foils are combined together. Before the adhesive is cured, one layer of metal foil is die-cut by a die-cutting method to remove unnecessary metal to form an intermediate circuit layer; when the die-cutting method is used for die-cutting, it is necessary to ensure that the adhesive has not been cured, so that the cut copper can be torn off. After the intermediate circuit layer is fabricated, a back solder mask is fabricated on the intermediate circuit layer, and the back solder mask employs a PI (Polyimide) film. Specifically, the back solder mask is bonded and fixed to the intermediate circuit layer by adhesive.

### Embodiment 3

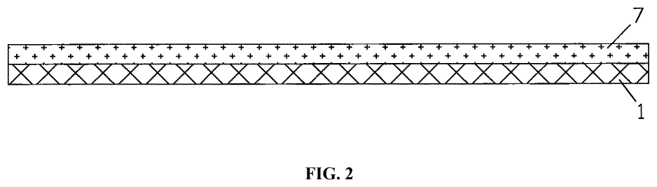

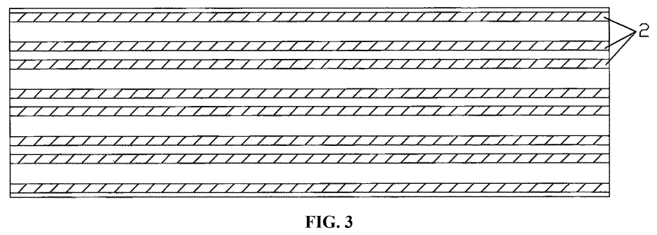

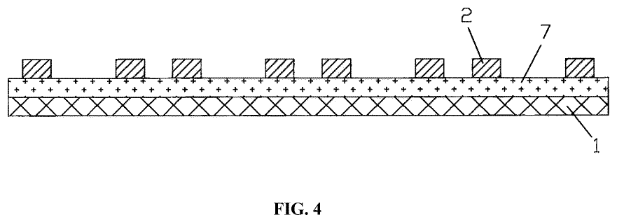

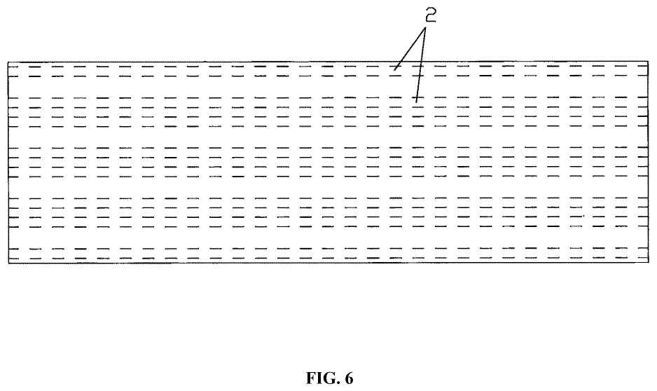

A PET thin film, a copper-aluminum-clad metal foil and a copper conductor are prepared. An adhesive is coated on the copper-aluminum-clad metal foil, and the adhesive employs an epoxy adhesive, or the adhesive is coated on both the copper-aluminum-clad metal foil and the PET thin film, and then the PET thin film, the copper conductor and the copper-aluminum-clad metal foil are vertically stacked to integrate the PET thin film, the copper conductor and the copper-aluminum-clad metal foil. The copper conductor is located between the PET thin film and the copper-aluminum-clad metal foil to form an intermediate circuit layer, referring to FIG. 1 for specific details. A thin film 1 made of PET is prepared, and then an adhesive 7 is coated to obtain a structure shown in FIG. 2, and then a conductor 2 is bonded to the thin film 1 to obtain structures shown in FIG. 3 and FIG. 4, and then a hole-free metal foil 3 made from copper-coated aluminum is coated with the adhesive and then bonded to a surface of the conductor 2 to obtain a structure shown in FIG. 6.

### Embodiment 4

A thin film with a metal layer and a metal foil are prepared, there is an adhesive between the thin film and the metal layer, where the metal layer is a copper layer, and the thin film with the copper layer is called a single-sided copper-clad laminate, and the fabrication of the single-sided copper-clad laminate is the prior art, or the single-sided copper-clad laminate may be directly purchased from the market. The thin film employs a PI film, and the metal foil is a copper foil. The copper layer on the thin film is fabricated into an intermediate circuit layer by an etching method or die-cutting method. Specifically, when the adhesive between the thin film and the metal layer is not cured, the intermediate circuit layer can be manufactured by using the die-cutting method, and after the adhesive between the thin film and the metal layer is cured, the intermediate circuit layer can be fabricated by using the etching method, where the etching method and the die-cutting method are both conventional technologies for fabricating the circuit layer in the industry and thus will not be described in detail here. An adhesive is applied to the copper foil or the intermediate circuit layer, the adhesive employs a commercially available polyurethane adhesive, the thin film with the intermediate circuit layer and the metal foil are vertically stacked to integrate the thin film, the intermediate circuit layer and the metal foil, where the intermediate circuit layer is located between the thin film and the metal foil.

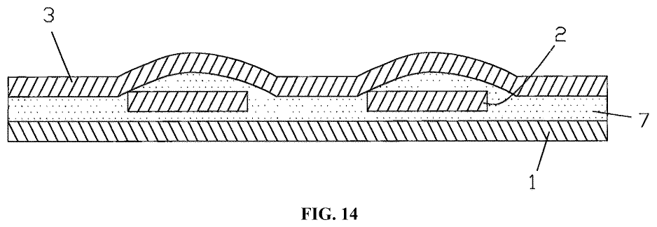

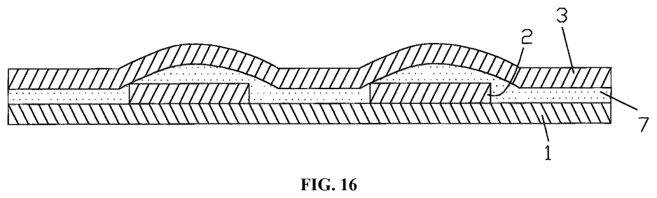

In foregoing Embodiment 1 to Embodiment 4, the metal foil overlaps with the intermediate circuit layer at partial positions to form double-layer metal positions, and the metal foil forms a single-layer metal position at a position other than the intermediate circuit layer, so a metal thickness of the double-layer metal position is greater than that of the single-layer metal position. The double-layer metal position, due to a larger metal thickness, has a higher current load, while the single-layer metal position, due to a smaller thickness, has a lower current load. At the double-layer metal position, the metal foil and the intermediate circuit layer are bonded and fixed by the adhesive, so that the insulating film between the metal foil and the intermediate circuit layer is omitted (in the prior art, the insulating film mostly employs a PI film or PET film). Because the adhesive is in an uncured state when the metal foil and the intermediate circuit layer are laminated, and a thickness of the adhesive itself is not large, the adhesive between the two layers of metals are able to be partially squeezed away under the action of a lamination pressure, so that the metal foil and the intermediate circuit layer are in contact with each other. More specifically, with reference to FIG. 14 and FIG. 16. For the intermediate circuit layer, it has certain sharp edges. During lamination, these sharp edges pierce through the uncured adhesive to form piercing holes in the adhesive. The sharp edges, after penetrating through the piercing holes, come into contact with the metal foil to achieve conduction.

In FIG. 14 and FIG. 16, the piercing hole only penetrates the adhesive. To implement a more reliable conduction between the metal foil and the intermediate circuit layer and prevent the circuit board from possible conduction fault, an independent piercing hole may also be additionally formed. Specifically, a pressing die with multiple extrusion pins is used, the extrusion pin is aligned with a surface of the back solder mask for extrusion, the adhesive between the intermediate circuit layer and the metal foil is squeezed away to form a piercing hole. The metal foil and the intermediate circuit layer make contact at the piercing hole to achieve conduction. Alternatively, the extrusion pin not only squeezes out the adhesive between the metal foil and the intermediate circuit layer, but also pierces through the intermediate circuit layer, so that the piercing hole penetrates the adhesive and the intermediate circuit layer. Alternatively, the extrusion pin is aligned with the surface of the metal foil for extrusion to squeeze out the adhesive between the intermediate circuit layer and the metal foil to form a piercing hole. Alternatively, the extrusion pin not only squeezes out the adhesive between the metal foil and the intermediate circuit layer, but also pierces the metal foil, making the piercing hole penetrate the adhesive and the metal foil. Alternatively, the extrusion pins can also be arranged on both sides, that is, the extrusion pin on one side is aligned with the surface of the metal foil, and the extrusion pin on the other side is aligned with the surface of the back solder mask, so that the extrusion pin not only can squeeze out the adhesive, but also can pierce the metal foil and the intermediate circuit layer, making the piercing hole penetrate the adhesive, the metal foil and the intermediate circuit layer. When the piercing holes are formed in the intermediate circuit layer or the metal foil, hole edges of the piercing holes axially extend to form a burr-like structure, and after the burr-like structure pass through the adhesive, the metal foil is in contact and conduction with the intermediate circuit layer at part or all piercing holes.

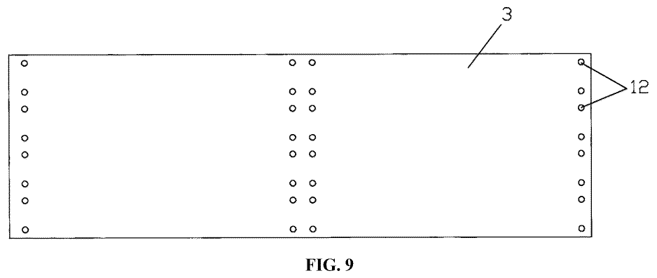

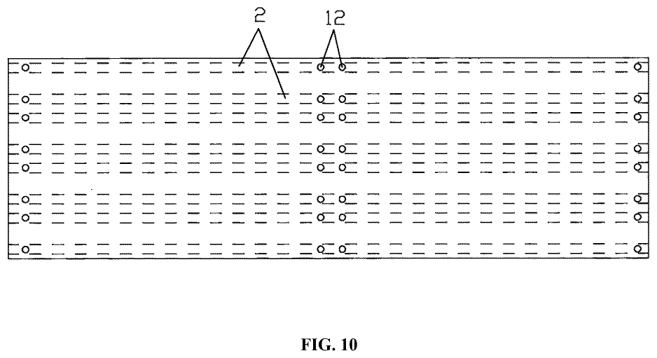

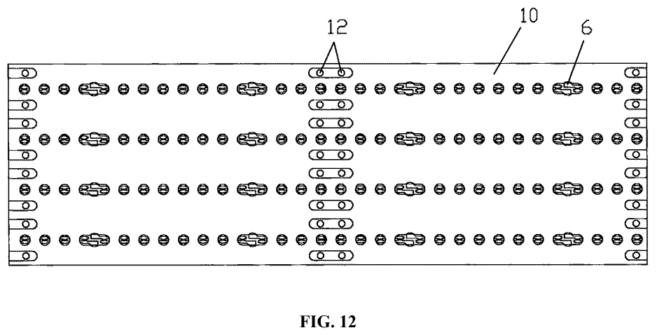

To implement more reliable conduction between the metal foil and the intermediate circuit layer, the piercing hole may also be fabricated by the following way. Specifically, as shown in FIG. 9, FIG. 9 is a copper foil with an adhesive, that is, the copper foil has been coated with the adhesive, and then the copper foil and the adhesive thereon are punctured by using equipment such as an extrusion pin or a drilling rig to obtain a piercing hole 12, and the adhesive-backed copper foil with the piercing hole 12 shown in FIG. 9 is attached to the intermediate circuit layer to obtain a wire-embedded metal-clad laminate shown in FIG. 10. When the wire-embedded metal-clad laminate shown in FIG. 10 is fabricated into an LED light strip, solder can be used in the piercing hole 12 to ensure a reliable conduction between a front circuit layer and the intermediate circuit layer. Further, the piercing hole 12 may also be used as a bonding pad for soldering an external power supply. As shown in FIG. 12, the piercing hole 12 is formed in a scissor position, and consumers can cut the LED light strip at the scissor position as needed, and then connect the positive and negative conductors to the piercing hole 12 at a cut position via soldering.

In the foregoing embodiments, the intermediate circuit layer may be made of any one of copper, aluminum, copper-clad aluminum, copper-aluminum composite, or copper-clad steel; and the metal foil on the intermediate circuit layer may be made of any one of copper, copper-coated aluminum, nickel-coated aluminum, or a tin-coated aluminum.

An embodiment of the second aspect of the present disclosure provides a fabrication method for a circuit board, including the fabrication method for a wire-embedded metal-clad laminate according to any embodiment in the first aspect, and further including fabricating a metal foil on an intermediate circuit layer into a circuit to form a front circuit layer, and fabricating a front solder mask on the front circuit layer. On the basis of the foregoing Embodiment 1 to Embodiment 4, the method is specifically as follows.

### Embodiment 5

Before the adhesive between the metal foil and the intermediate circuit layer is cured, the metal foil is subjected to die-cutting by using a die-cutting method to tear away unnecessary metal, enabling the metal foil to form the front circuit layer. The front solder mask is an adhesive-backed cover film, the cover film is bonded to the front circuit layer, pressed by a press machine, and heating is carried out after pressing to cure the adhesive and the adhesive on the cover film, so that the adhesive and the adhesive on the cover film can be synchronously cured through one-time pressing and heating, so that the process is reduced, and the production efficiency is improved.

### Embodiment 6

Before the adhesive between the metal foil and the intermediate circuit layer is cured, the metal foil is subjected to die-cutting by using a die-cutting method to tear away unnecessary metal, enabling the metal foil to form the front circuit layer. Then, pressing is carried out to make the bonding between the front circuit layer and the intermediate circuit layer firm, and then the solder mask ink is printed on the front circuit layer (the solder mask ink is commonly used in the industry), and after the solder mask ink is printed, heating treatment is carried out to cure the adhesive and the solder mask ink.

### Embodiment 7

After the adhesive between the metal foil and the intermediate circuit layer is cured, the metal foil is etched by an etching method to form a front circuit layer, the reason of etching after the adhesive is cured is that a caustic soda solution, specifically a sodium hydroxide solution, is used in the etching process, and caustic soda is prone to destroying the uncured adhesive. After the front circuit layer is fabricated by the etching method, the cover film with adhesive is selected as a front solder mask, and the cover film is bonded to the front circuit layer. Then, after pressing and heating processes, the adhesive on the cover film is cured, and the cover film can be firmly and reliably bonded to the front circuit layer.

### Embodiment 8

After the adhesive between the metal foil and the intermediate circuit layer is cured, the metal foil is etched by an etching method to form a front circuit layer, the reason of etching after the adhesive is cured is that a caustic soda solution, specifically a sodium hydroxide solution, is used in the etching process, and caustic soda is prone to destroying the uncured adhesive. After the front circuit layer is fabricated by the etching method, the solder mask ink is selected as a front solder mask, the solder mask ink is directly printed on the front circuit layer. Then, after heating, the solder mask ink is cured, so that the solder mask ink is firmly and reliably bonded to the front circuit layer.

### Embodiment 9

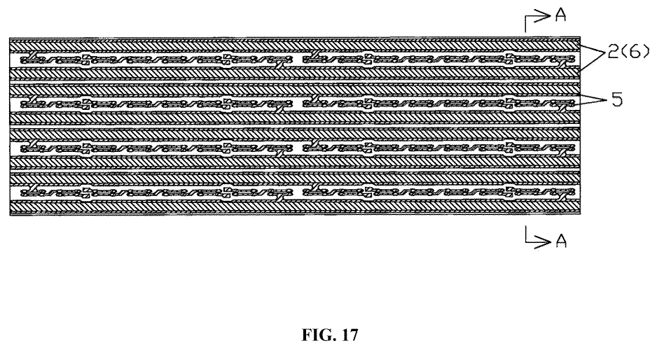

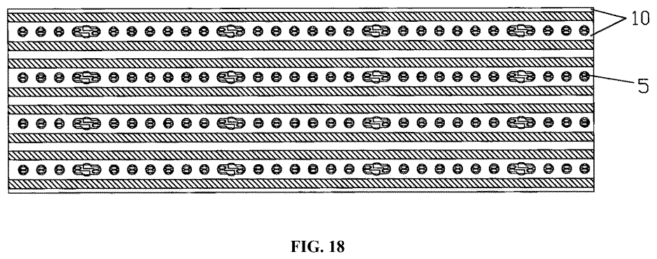

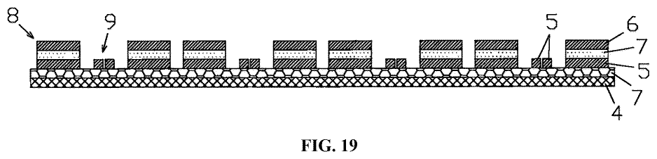

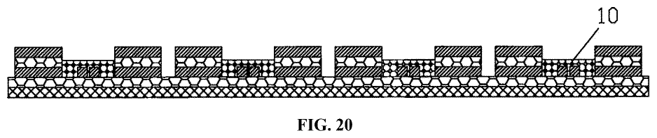

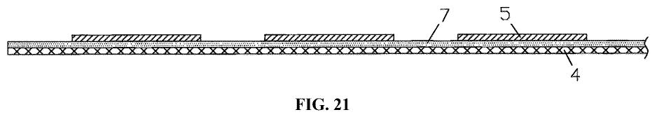

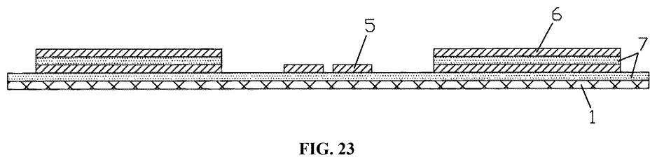

An embodiment of a second aspect of the present disclosure further provides another fabrication method for a circuit board, including the following steps. A single-sided metal-clad laminate (in this embodiment, a PET film is bonded to a copper layer, which is called a single-sided copper-clad laminate) and a conductor (in this embodiment, the copper is used as the conductor), where the single-sided copper-clad laminate includes a thin film, a copper layer and an adhesive therebetween, and the metal layer on the single-sided copper-clad laminate is fabricated into an intermediate circuit layer by using a die-cutting method or etching method. Specifically, before the adhesive between the thin film and the copper layer is cured, the intermediate circuit layer is fabricated by using the die-cutting method, and after the adhesive between the thin film and the copper layer is cured, the intermediate circuit layer is fabricated by using the etching method. The conductor is bonded to the front of the intermediate circuit layer by the adhesive, the front circuit layer is formed the conductor, so that the front circuit layer and the intermediate circuit layer overlap at partial positions to form double-layer metal positions, and the front circuit layer and the intermediate circuit layer do not overlap at partial positions to form a single-layer metal position, where a metal thickness of the double-layer metal position is greater than that of the single-layer metal position. At the double-layer metal position, the front circuit layer and the intermediate circuit layer are bonded and fixed by the adhesive, and the front circuit layer is in conduction with the intermediate circuit layer. A front solder mask is arranged on the front circuit layer and/or the intermediate circuit layer. Specifically, as shown in FIG. 17 which is a diagram of a planar structure when a conductor 2 is bonded to an intermediate circuit layer 5 by an adhesive, it can be learned that the conductor 2 is stacked over the intermediate circuit layer 5, the intermediate circuit layer 5 overlaps with the conductor at a main positive/negative bus position, and no conductor 2 is not stacked over an auxiliary line position. As shown in FIG. 18, after the conductor 2 is bonded to the intermediate circuit layer 5, a front solder mask 10 is fabricated on the intermediate circuit layer 5, and a bonding pad window is formed in the front solder mask 10. When an LED light strip is fabricated, an electronic component is soldered to the intermediate circuit layer through the bonding pad window. It may be understood that that front solder mask may also be simultaneously arranged on the front circuit layer formed by the conductor and the intermediate circuit layer, so that the conductor is not exposed. FIG. 19 and FIG. 20 are divided into cross-sectional diagrams (longitudinal cross section) of FIG. 17 and FIG. 18, FIG. 17-FIG. 20 show a multi-row circuit board (4 rows). Also, with reference to FIG. 21, which is a cross-sectional diagram of a single circuit board. The cross-section does not pass through the front circuit layer and shows a single-layer metal position. FIG. 23 is a cross-sectional diagram of a single circuit board in a longitudinal direction, showing a double-layer metal position, and FIG. 23 also shows a bonding pad 11. The difference between Embodiment 9 and Embodiment 5 to Embodiment 8 is that in Embodiments 5 to 8, the metal foil is located on the intermediate circuit layer. When the metal foil is die-cut or etched to form a circuit layer, the circuit layer is the front circuit layer. In Embodiment 9, when the metal layer on the single-sided metal-clad laminate is etched or die-cut to form the circuit layer, the circuit layer is used as the intermediate circuit layer, and the conductor is bonded onto the intermediate circuit layer by the adhesive to form the front circuit layer. Embodiment 9 has the same technical effect as Embodiments 5 to 8. That is, in Embodiment 9, the front circuit layer and the intermediate circuit layer overlap at partial positions to form double-layer metal positions, while the front circuit layer and the intermediate circuit layer do not overlap at partial positions to form single-layer metal positions, so that a metal thickness of the double-layer metal position is greater than that of the single-layer metal position. The double-layer metal position, due to its larger metal thickness, has a higher current load, while the single-layer metal bit, due to its smaller metal thickness, has a lower current load. At the double-layer metal position, the front circuit layer and the intermediate circuit layer are bonded and fixed by the adhesive, so that the use of an insulating film between the front circuit layer and the intermediate circuit layer is omitted. As the adhesive itself is not thick and is subjected to lamination pressure during the lamination of the front circuit layer and the intermediate circuit layer, the uncured adhesive between the front circuit layer and the intermediate circuit layer will be partially squeezed away to form piercing holes. This allows the front circuit layer and the intermediate circuit layer to make contact, thereby achieving conduction between the front circuit layer and the intermediate circuit layer.

With regard to the conduction between the front circuit layer and the intermediate circuit layer, to implement a more reliable conduction between the front circuit layer and the intermediate circuit layer, the piercing holes can be achieved by a die with extrusion pins, so that the piercing holes only penetrate the adhesive, penetrate the adhesive and the intermediate circuit layer, penetrate the adhesive and the front circuit layer, or penetrate the adhesive, the front circuit layer and the intermediate circuit layer. When the piercing holes are formed in the intermediate circuit layer or the front circuit layer, because the intermediate circuit layer and the front circuit layer are made of metal, hole edges of the piercing holes extend axially to form a burr-like structure, and after the burr-like structure passes through the adhesive, the front circuit layer and the intermediate circuit layer are in contact and conduction with the intermediate circuit layer at part or all of the piercing holes.

On the basis of methods in Embodiments 1 to 4, an embodiment in a third aspect of the present disclosure can be obtained. A wire-embedded metal-clad laminate includes a back solder mask, an intermediate circuit layer, and a metal foil, where the back solder mask, the intermediate circuit layer and the metal foil are vertically stacked in turn, an adhesive is formed between the back solder mask and the metal foil, and the back solder mask, the intermediate circuit layer and the metal foil are combined together by the adhesive, the metal foil overlaps with the intermediate circuit layer at partial positions to form double-layer metal positions, the metal foil forms a single-layer metal position at a position other than the intermediate circuit layer, and a metal thickness of the double-layer metal position is greater than that of the single-layer metal position. At the double-layer metal position, the metal foil and the intermediate circuit layer are bonded and fixed by the adhesive, and the metal foil and the intermediate circuit layer are in conduction with each other.

In this embodiment, the intermediate circuit layer is made of copper, aluminum, copper-clad aluminum, copper-aluminum composite, or copper-clad steel; and the metal foil on the intermediate circuit layer is made of copper, copper-coated aluminum, nickel-coated aluminum, or tin-coated aluminum.

On the basis of the methods in Embodiments 5 to 9, a fourth aspect embodiment of the present disclosure can be obtained. A circuit board includes a back solder mask 4, an intermediate circuit layer 5, and a front circuit layer 6, where the back solder mask 4, the intermediate circuit layer 5 and the front circuit layer 6 are vertically stacked in turn. The circuit board further includes an adhesive 7, and the adhesive 7 is configured to combine the back solder mask 4, the intermediate circuit layer 5 and the front circuit layer 6 together, the front circuit layer 6 and the intermediate circuit layer 5 overlap at partial positions to form double-layer metal positions 8, the front circuit layer 6 and the intermediate circuit layer 5 do not overlap at partial positions to form single-layer metal positions 9, and a metal thickness of the double-layer metal position 8 is greater than that of the single-layer metal position 9. At the double-layer metal position 8, the front circuit layer 6 and the intermediate circuit layer 5 are bonded and fixed by the adhesive 7, and the front circuit layer 6 is in conduction with the intermediate circuit layer 5. The circuit board further includes a front solder mask 10, which is arranged on the front circuit layer 6 and/or the intermediate circuit layer 5. In FIG. 19, the front solder mask 10 has not been fabricated on the circuit board. In FIG. 20, the front solder mask 10 has been fabricated on the intermediate circuit layer 5, and the front solder mask 10 is fabricated on the intermediate circuit layer 5. It may be understood that the front solder mask may also be fabricated on the front circuit layer, or the front solder mask layer is formed on both the front circuit layer and the intermediate circuit layer, and the front solder mask may be a solder mask cover film or solder mask ink.

To achieve the conduction between the front circuit layer 6 and the intermediate circuit layer 5, in some embodiments of the present disclosure, the double-layer metal position is provided with a piercing hole (not shown in the figure, which may refer to FIG. 14 and FIG. 16), and the piercing hole penetrates the adhesive 7. In some other embodiments, the piercing hole penetrates the adhesive 7 and the front circuit layer 6. In some other embodiments, the piercing hole penetrates the adhesive 7 and the intermediate circuit layer 5. In some other embodiments, the piercing hole penetrates the adhesive 7, the front circuit layer 6 and the intermediate circuit layer 5. Therefore, the front circuit layer 6 may be in contact and conduction with the intermediate circuit layer 5 at part or all of the piercing holes.

In some embodiments of the present disclosure, a thickness of the adhesive 7 between the front circuit layer 6 and the intermediate circuit layer 5 is 3 μm to 100 μm. If the adhesive is too thin, it is not conducive to the bonding between the front circuit layer 6 and the intermediate circuit layer 5, and if the adhesive 7 is too thick, it is not conducive to the contact and conduction between the front circuit layer and the intermediate circuit layer, and it is also not conducive to reducing the fabrication cost of the circuit board when the adhesive is increased.

In some embodiments of the present disclosure, each of the front circuit layer 6 and the intermediate circuit layer 5 is made of one or two of copper, aluminum, or a combination of copper-aluminum, copper-steel, aluminum-nickel, or aluminum-tin, and the front circuit layer and the intermediate circuit layer are made of a same metal or different metals. The metal range available for the front circuit layer and the intermediate circuit layer is expanded. Especially, for the circuit layer which does not need to be soldered with an electronic component, aluminum with poor tin affinity can be directly used. As shown in FIG. 19 and FIG. 20, the front circuit layer 6 may employ the aluminum, which not only reduces the production cost, but also does not affect the reliable conduction between the front circuit layer and the intermediate circuit layer.

It may be understood that when one of the front circuit layer 6 and the intermediate circuit layer 5 is aluminum, the other is a metal other than aluminum, at least one of the front circuit layer 6 and the intermediate circuit layer 5 is used for soldering the electronic component. When the front circuit layer 6 and the intermediate circuit layer 5 both employ the aluminum, the soldering and fixing of the electronic component are affected by means of soldering.

In some embodiments of the present disclosure, the adhesive 7 is an acrylic adhesive, an epoxy adhesive, or a polyurethane adhesive. When this type of adhesive is in an uncured state, it is easily squeezed away to form piercing holes when subjected to lamination or extrusion by an extrusion pin. After curing, it has a good bonding force to combine the front circuit layer and the intermediate circuit layer well.

In a fifth aspect embodiment of the present disclosure, an LED light strip is provided, including the circuit board according to any one embodiment in the fourth aspect, and further including an electronic component soldered to the front circuit layer or the intermediate circuit layer. As shown in FIG. 19 and FIG. 20, the front solder mask 10 is arranged on the intermediate circuit layer 5, the electronic component is soldered to the intermediate circuit layer, specifically, the electronic component is soldered to a bonding pad exposed from the bonding pad window of the front solder mask of the intermediate circuit layer.

To further improve the reliability of conduction between the front circuit layer and the intermediate circuit layer, in some embodiments of the present disclosure, the double-layer metal position is provided with multiple piercing holes, a conductive substance is arranged in part or all piercing holes. The conductive substance is used to electrically connect the front circuit layer and the intermediate circuit layer and may be tin or copper. Specifically, when the electronic component is soldered, the tin can be soldered in the piercing hole, or electroplated copper may be formed in the piercing hole by an electroplating way.

The intermediate circuit layer and the front circuit layer are directly bonded by means of the adhesive, the characteristics that the front circuit layer and the intermediate circuit layer need to be electrically connected when being fabricated into a circuit board are utilized, the technical prejudice in the prior art that an insulating film is required to insulate and separate the two layers of metals and then the conduction between the two layers of metals can be achieved through via holes on the front circuit layer is abandoned, and the fabrication cost of the circuit board is reduced. Because the adhesive is in an uncured state when the intermediate circuit layer and the front circuit layer are bonded and fixed by the adhesive, the adhesive between the intermediate circuit layer and the front circuit layer is partially squeezed away in the pressing process to promote the contact and conduction between the intermediate circuit layer and the front circuit layer, making it unnecessary to form via holes in the front circuit layer, and allowing one of the circuit layers to be made of aluminum. This avoids the problems in the prior art that electroplated copper and solder either fail to combine with aluminum or involving complex processes, so that the fabrication cost of the circuit board is further reduced, and the structure of the circuit board is simplified. Canceling the use of the insulating film also can reduce the weight of the circuit board. Therefore, the fabricated circuit board and LED light strip have lighter weight, which is beneficial to the hanging use of the long LED light strip and can prevent the long LED light strip from loosening or breaking due to its own weight.

The embodiments of the present disclosure have been described in detail above with reference to the accompanying drawings, but the present disclosure is not limited to the above embodiments, and various changes can be made within the knowledge of those of ordinary skill in the art without departing from the purpose of the present disclosure.

1. A fabrication method for a wire-embedded metal-clad laminate, comprising:
preparing a conductor, a metal foil, and an adhesive, adhering and fixing the conductor to the metal foil by the adhesive, fabricating a back solder mask on the conductor, wherein an intermediate circuit layer is formed by the conductor; or preparing metal foils and an adhesive, and combining two layers of metal foils together by the adhesive, and carrying out die-cutting on one layer of metal foil by a die-cutting method to remove unnecessary metal and form an intermediate circuit layer, and fabricating a back solder mask on the intermediate circuit layer; or preparing a thin film, a metal foil and a conductor, applying an adhesive on the metal foil or on the metal foil and the thin film, vertically stacking the thin film, the conductor and the metal foil to integrate the thin film, the conductor and the metal foil, wherein the conductor is located between the thin film and the metal foil to form an intermediate circuit layer; or preparing a thin film with a metal layer and a metal foil, fabricating the metal layer on the thin film into an intermediate circuit layer by an etching or die-cutting method, applying an adhesive on the metal foil or the intermediate circuit layer, and vertically stacking the thin film with the intermediate circuit layer and the metal foil to integrate the thin film, the intermediate circuit layer and the metal foil, wherein the intermediate circuit layer is located between the thin film and the metal foil; wherein
the metal foil overlaps with the intermediate circuit layer at partial positions to form double-layer metal positions, the metal foil forms a single-layer metal position at a position other than the intermediate circuit layer, and a metal thickness of the double-layer metal position is greater than that of the single-layer metal position; at the double-layer metal position, the metal foil and the intermediate circuit layer are bonded and fixed by the adhesive, and the metal foil is in conduction with the intermediate circuit layer.

2. The fabrication method for a wire-embedded metal-clad laminate according to claim 1, wherein the double-layer metal position is provided with piercing holes, which penetrate the adhesive, penetrate the adhesive and the metal foil, penetrate the adhesive, and the intermediate circuit layer, or penetrate the adhesive, the metal foil and the intermediate circuit layer, such that the metal foil and the intermediate circuit layer are in contact and conduction with each other at a part or all of the piercing holes.

3. The fabrication method for a wire-embedded metal-clad laminate according to claim 1, wherein the intermediate circuit layer is made of copper, aluminum, copper-clad aluminum, copper-aluminum composite, or copper-clad steel; and the metal foil on the intermediate circuit layer is made of copper, copper-aluminum composite, nickel-coated aluminum, or tin-coated aluminum.

4. The fabrication method for a wire-embedded metal-clad laminate according to claim 1, wherein the adhesive is an acrylic adhesive, epoxy adhesive or polyurethane adhesive in a semi-cured state.

5. A fabrication method for a circuit board, comprising the fabrication method for a wire-embedded metal-clad laminate according to claim 1, and further comprising fabricating a metal foil on an intermediate circuit layer into a circuit to form a front circuit layer, and fabricating a front solder mask on the front circuit layer.

6. The fabrication method for a circuit board according to claim 5, comprising carrying out die-cutting on the metal foil by a die-cutting method before an adhesive between the metal foil and the intermediate circuit layer is cured, and tearing away unnecessary metal to form the front circuit layer by the metal foil; or after the adhesive between the metal foil and the intermediate circuit layer is cured, etching the metal foil by an etching method to form the front circuit layer.

7. The fabrication method for a circuit board according to claim 6, wherein the front circuit layer is fabricated by the die-cutting method, the front solder mask is a cover film with an adhesive, the cover film is bonded to the front circuit layer, and then pressing and heating are carried out to cure the adhesive and the adhesive on the cover film; or the front circuit layer is fabricated by the die-cutting method, the front solder mask is solder mask ink, the wire-embedded metal-clad laminate is die-cut to fabricate a circuit, and then pressed; then the solder mask ink is printed on the front circuit layer and heated, with the adhesive and the solder mask ink cured while heating.

8. The fabrication method for a circuit board according to claim 6, wherein the front circuit layer is fabricated by the etching method, the metal-clad laminate is pressed and heated for curing, and then the metal foil is etched to form the front circuit layer, the front solder mask is a cover film with an adhesive, the cover film is bonded to the front circuit layer, and pressing and heating are carried out to cure the adhesive on the cover film; or the front circuit layer is fabricated by the etching method, the metal-clad laminate is cured by pressing and heating, and the metal foil is etched to form the front circuit layer; the front solder mask is solder mask ink, the solder mask ink is printed on the front circuit layer, and the solder mask ink is cured by heating.

9. A fabrication method for a circuit board, comprising: preparing a single-sided metal-clad laminate and a conductor, fabricating a metal layer on the single-sided metal-clad laminate into an intermediate circuit layer by a die-cutting method or etching method, bonding the conductor to the front of the intermediate circuit layer by an adhesive, wherein a front circuit layer is formed by the conductor, so that the front circuit layer and the intermediate circuit layer overlap at partial positions to form double-layer metal positions, and the front circuit layer and the intermediate circuit layer do not overlap at partial positions to form single-layer metal positions, and a metal thickness of the double-layer metal position is greater than that of the single-layer metal position; at the double-layer metal position, bonding and fixing the front circuit layer and the intermediate circuit layer by the adhesive, and enabling the front circuit layer to be in conduction the intermediate circuit layer; and disposing a front solder mask on the front circuit layer and/or the intermediate circuit layer.

10. The fabrication method for a circuit board according to claim 9, wherein the double-layer metal position is provided with piercing holes, which penetrate the adhesive, penetrate the adhesive and the front circuit layer, penetrate the adhesive and the intermediate circuit layer, or penetrate the adhesive, the front circuit layer and the intermediate circuit layer, such that the front circuit layer and the intermediate circuit layer are in contact and conduction with each other at a part or all of the piercing holes.

11. A wire-embedded metal-clad laminate, comprising a back solder mask, an intermediate circuit layer, and a metal foil, wherein the back solder mask, the intermediate circuit layer and the metal foil are vertically stacked in turn, an adhesive is formed between the back solder mask and the metal foil, and the back solder mask, the intermediate circuit layer and the metal foil are combined together by the adhesive, the metal foil overlaps with the intermediate circuit layer at partial positions to form double-layer metal positions, the metal foil forms a single-layer metal position at a position other than the intermediate circuit layer, and a metal thickness of the double-layer metal position is greater than that of the single-layer metal position; and at the double-layer metal position, the metal foil and the intermediate circuit layer are bonded and fixed by the adhesive, and the metal foil is in conduction with the intermediate circuit layer.

12. The wire-embedded metal-clad laminate according to claim 11, wherein the double-layer metal position is provided with piercing holes, which penetrate the adhesive, penetrate the adhesive and the metal foil, penetrate the adhesive and the intermediate circuit layer, or penetrate the adhesive, the metal foil and the intermediate circuit layer, such that the metal foil and the intermediate circuit layer are in contact and conduction with each other at a part or all of the piercing holes.

13. The wire-embedded metal-clad laminate according to claim 11, wherein the intermediate circuit layer is made of copper, aluminum, copper-clad aluminum, copper-aluminum composite, or copper-clad steel; and the metal foil on the intermediate circuit layer is made of copper, copper-aluminum composite, nickel-coated aluminum, or tin-coated aluminum.

14. A circuit board, comprising a back solder mask, an intermediate circuit layer, and a front circuit layer, wherein the back solder mask, the intermediate circuit layer and the front circuit layer are vertically stacked in turn; the circuit board further comprises an adhesive, the adhesive is configured to combine the back solder mask, the intermediate circuit layer and the front circuit layer together, the front circuit layer and the intermediate circuit layer overlap at partial positions to form double-layer metal positions, the front circuit layer and the intermediate circuit layer do not overlap at partial positions to form single-layer metal positions, and a metal thickness of the double-layer metal position is greater than that of the single-layer metal position; at the double-layer metal position, the front circuit layer and the intermediate circuit layer are bonded and fixed by the adhesive, and the front circuit layer is in conduction with the intermediate circuit layer; and the circuit board further comprises a front solder mask, which is arranged on the front circuit layer and/or the intermediate circuit layer.

15. The circuit board according to claim 14, wherein the double-layer metal position is provided with piercing holes, which penetrate the adhesive, penetrate the adhesive and the front circuit layer, penetrate the adhesive and the intermediate circuit layer, or penetrate the adhesive, the front circuit layer and the intermediate circuit layer, such that the front circuit layer and the intermediate circuit layer are in contact and conduction with each other at a part or all of the piercing holes.

16. The circuit board according to claim 14, wherein the adhesive between the front circuit layer and the intermediate circuit layer has a thickness of 3 μm to 100 μm.

17. The circuit board according to claim 14, wherein the front solder mask is a cover film, or solder mask ink.

18. The circuit board according to claim 14, wherein each of the front circuit layer and the intermediate circuit layer is made of one or two of copper, aluminum, or a combination of copper-aluminum, copper-steel, aluminum-nickel, or aluminum-tin, and the front circuit layer and the intermediate circuit layer are made of a same metal or different metals.

19. The circuit board according to claim 18, wherein when either of the front circuit layer or the intermediate circuit layer is made of aluminum, the other is a metal other than aluminum.

20. The circuit board according to claim 14, wherein the adhesive is an acrylic adhesive, epoxy adhesive, or polyurethane adhesive.

21. An LED (Light Emitting Diode) light strip, comprising the circuit board according to claim 14, and an electronic component soldered to a front circuit layer or an intermediate circuit layer.

22. The LED light strip according to claim 21, wherein a double-layer metal position is provided with a plurality of piercing holes, conductive substances are arranged in part or all of the piercing holes, and the front circuit layer and the intermediate circuit layer are electrically connected by the conductive substance.

23. (canceled)
